(19) United States
(12) Patent Application Publication
(10) Pub. No.: US 2012/0181668 A1
(43) Pub. Date: Jul. 19, 2012

(54) INK JET PRINTABLE ETCHING INKS AND ASSOCIATED PROCESS

(75) Inventors: Oliver Doll, Dietzenbach (DE); Edward Plummer, Muenster (DE); Mark James, Romsey (GB); Ingo Koehler, Reinheim (DE); Lana Nanson, Southampton (GB)

(73) Assignee: MERCK PATENT GESELLSCHAFT MIT BESCHRANKTER HAFTUNG, Darmstadt (DE)

(21) Appl. No.: 13/496,608

(22) PCT Filed: Aug. 20, 2010
(86) PCT No.: PCT/EP2010/005133

§ 371 Date: Mar. 16, 2012

(30) Foreign Application Priority Data
Sep. 18, 2009 (EP) 09011919.9

(51) Int. Cl. H01L 29/06; C09K 13/00; H01L 21/306

(52) U.S. Cl. 257/618; 438/746; 252/79.1; 257/E21.215; 257/E29.006

(57) ABSTRACT

The present invention refers to a method for contactless deposition of new etching compositions onto surfaces of semiconductor devices as well as to the subsequent etching of functional layers being located on top of these semiconductor devices. Said functional layers may serve as surface passivation layers and/or anti-reflective coatings (ARCs).

The present invention refers to a method for contactless deposition of new etching compositions onto surfaces of semiconductor devices as well as to the subsequent etching of functional layers being located on top of these semiconductor devices. Said functional layers and layer stacks may serve for purpose of surface passivation layers and/or anti-reflective behaviour, so-called anti-reflective coatings (ARCs).

Surface passivation layers for semiconductors mostly comprise the use of silicon dioxide (SiO₂) and silicon nitride (SiNₓ) as well as stacks composed of alternating layers of silicon dioxide and silicon nitride, commonly known as NO— and ONO-stacks [1], [2], [3], [4], [5]. The surface passivation layers may be brought onto the semiconductor using well-known state-of-the-art deposition technologies, such as chemical vapour deposition (CVD), plasma-enhanced chemical vapour deposition (PECVD), sputtering, as well as thermal treatment in course of the exposure of semiconductors to an atmosphere comprising distinct gases and/or mixtures thereof. Thermal treatment may comprise in more detail methods like “dry” and “wet” oxidation of silicon as well as nitridation of silicon oxide and vice versa oxidation of silicon nitride. Furthermore, surface passivation layers may also be composed of a stack of layers being beyond from above-mentioned example of NO- and ONO-stacks. Such passivating stacks may comprise a thin layer (10-50 nm) of amorphous silicon (a-Si) deposited directly on the semiconductor surface, which is either covered by a layer of silicon oxide (SiOₓ) or by silicon nitride (SiNₓ) [6], [7]. An other type of stack, which will typically be used for surface passivation, is composed of aluminium oxide (AlOₓ), which may be brought onto the semiconductor surface by low temperature deposition (→ low temperature passivation) applying ALD-technology, finished or capped by silicon oxide (SiOx) [8], [9]. As an alternative capping layer, however, silicon nitride may also be conceivable. However, effective surface passivation is also achieved when singly using above-mentioned low temperature passivation comprising ALD-deposited aluminium oxide.

Anti-reflective layers are typical parts of state-of-the-art solar cells serving for an increase of the conversion efficiency of solar cells induced by achieving an improved capability to trap the incident light within the solar cell (optical confinement). Typical ARCs are composed of stoichiometric as well as non-stoichiometric silicon nitride (SiNO, titanium oxide (TiOₓ) and also of silicon dioxide (SiOₓ) [1], [2], [3], [10].

All singly mentioned materials, including amorphous silicon (a-Si), may additionally be partially hydrogenated, namely hydrogen-containing. The individual hydrogen contents of the materials mentioned depends on individual parameters of deposition. In particular amorphous silicon (a-Si) may partially comprise ammonia (NH₃) intercalated or otherwise incorporated.

Innovative solar cell concepts often require that either surface passivation or anti-reflective layers have to be opened locally in order to build up certain structural features and/or to define regions bearing different electronic and electrical properties. Commonly, such layers may be structured by local deposition of etching pastes, by photolithography, by depositing a “positive” mask of common etch resists, where the deposition method may be either screen-printing or ink jetting, as well as by laser-induced local ablation of the material. Each of the above-mentioned technologies offers unique advantages, however, they also suffer from specific drawbacks. For instance, photolithography enables smallest feature sizes combined with a degree of very high accuracy. However, it is a time consuming process technology making it therefore very expensive, and as a consequence, it will not be applicable for the need of industrial high volume and high throughput manufacturing, thus, not addressing a specific need of crystalline silicon solar cell production in particular. Surface structuring by laser ablation bears the drawback of local laser-induced surface damage during dissipation of heat brought in by laser light. As a consequence, the surface becomes altered by melting and re-crystallization processes which may significantly affect the surface morphology, e.g. by locally destroying surface textures. Besides the latter undesirable effect, the surface has to be liberated from the laser-induced surface damage, which is most commonly caused by a wet-chemical post-laser treatment, for instance by etching with solutions comprising KOH and/or other alkaline etchants. On the other hand, deposition of material by ink jetting is by a first approach a strongly locally limited technique of deposition. Its resolution is somewhat better than that of screen-printing. However, the resolution is strongly influenced by the diameter of the droplets jetted from the print head. For instance, a droplet with a volume of 10 μl results in a droplet diameter of approximately 30 μm, which may spread on the surface when hitting it by an interaction of impact related deceleration and surface wetting. One of the striking benefits of ink jetting is, besides contactless deposition of functional materials, local deposition in combination with a low consumption of process chemicals. In principle, any kind of complex layout may be printed onto surfaces by just involving computer-aided designs (CAD) and transferring the digitalized printing layout to the printer and to the substrate, respectively. Another benefit of ink jet printing in comparison to photolithography is its tremendous potential to cut down the number of process steps essentially needed for surface structuring. Ink jetting comprises three major process steps only, whereas photolithography requires at least eight process steps. The main three steps are: a) deposition of ink, b) etching and c) cleaning of the substrate.

The current invention is related to the local structuring of photovoltaic devices, but is not strongly limited to this field of application. In general the manufacturing of electronic devices requires the structuring of any kind of surface layer, with typical layers on the surface including, but not limited to, silicon oxides and silicon nitrides. As such the ink jet system, namely the print head, must either be manufactured of materials that are compatible with typical chemicals used for the etching of silicon dioxide and/or silicon nitride. Alternatively the ink must be formulated to be chemically inert at ambient and slightly elevated temperatures, for instance at 80° C. Then the ink must distinctly evolve its etching capability on the heated substrate only.

### REFERENCES

[1] M. A. Green, Solar Cells, The University of New South Wales, Kensington, Australia, 1998
[2] M. A. Green, Silicon Solar Cells: Advanced Principles & Practice, Centre for Photovoltaic engineering, The University of New South Wales, Sydney Australia, 1995
[3] A. G. Aberle, Crystalline Silicon Solar Cells: Advanced Surface Passivation and Analysis, Centre for Photovoltaic engineering, The University of New South Wales, Sydney Australia, 2^{nd} edition, 2004
[3] I. Eisele, Grundlagen der Silicium-Halbleitertechnologie, Vorlesungsscript, Universitat der Bundeswehr, Neubiberg, revised edition 2000
[4] M. Hofmann, S. Kambor, C. Schmidt, D. Grambole, J. Rentsch, S. W. Glunz, R. Preu, Advances in Optoelectronics (2008), doi: 10.1155/2008/485467
[5] B. Bitnar, Oberflächenpassivierung von kristallinen Silicium-Solarzellen, PhD thesis, University of Konstanz, Germany, 1998
[6] S. Gatz, H. Plagwitz, P. P. alternatt, B. Terheiden, R. Brendel, Proceedings of the 23^{rd} European Photovoltaic Solar Energy Conference, 2008, 1033
[7] M. Hofmann, C. Schmidt, N. Kohn, J. rentsch, s. W. Glunz, R. Preu, Prog. Photovolt: Res. Appl. 2008, 16, 509-518
[8] J. Schmidt, A. Merkle, R. Bock, P. P. Alternatt, A. Cuevas, N. Harder, B. Hoex, R. van de Sanden, E. Kessels, R. Brendel, Proceedings of the 23^{rd} European Photovoltaic Solar Energy Conference, 2008, Valencia, Spain
[9] J. Schmidt, a. Merkle, R. Brendel, B. Hoex, C. M. van de Sanden, W. M. M. Kessels, Prog. Photovolt: Res. Appl. 2008, 16, 461-466
[10] B. S. Richards, J. E. Cotter, C. B. Honsberg, Applied Physics Letters (2002), 80, 1123

### OBJECTIVE

As disclosed in J. Org. Chem. 48, 2112-4 (1983) tetraalkylammonium fluoride salts (TAAF) are known to decompose thermally to tetraalkylammonium bifluorides. Especially suitable tetraalkylammonium fluoride salts are ammonium fluoride salts, wherein the alkyl denotes preferably at least a secondary alkyl group which may be decomposed to volatile olefin and active HF.

These tetraalkylammonium fluoride salts have been found to be very suitable in aqueous solution for the etching of surfaces composed of silicon oxides, nitrides, oxy-nitrides or similar surfaces, although TAAF's are known as additives in non corrosive cleaning baths (US2008/0004197 A).

In order to etch through silicon nitride/oxide films it is known using an inkjet printable fluoride based etchant. In this case inkjet printing is a favourable technique for deposition of these materials because:
It is a non-contact method and therefore advantageous for patterning fragile substrates.
As a digital technique images can be easily manipulated and a printer can be used to print rapidly a range of different patterns.
This method can provide better resolution than screen printing.
It is efficient in the use of material, cost saving and environment-friendly.

Ink jet (IJ) printing includes but is not limited to: piezo drop on demand (DOD) IJ, thermal DOD IJ, electrostatic DOD IJ, Tone Jet DOD, continuous IJ, aerosol jet, electro-hydrodynamic jetting or dispensing and other controlled spraying methods as for instance ultrasonic spraying.

However, known etching compositions, which are suitable for the etching of SiOₓ or SiNₓ based surfaces, usually are based on acidic fluoride solutions. In order to achieve permanently a steady etching result the ink jetting of the corrosive ink onto the surface has to be ensured and has to take place effectively and long-running.

Jetting the inks:
The inks must be compatible with the print head; simple acidic fluoride etchants may not be dispensed through the majority of print heads, because their construction is largely made of silicon and metallic components, which in general are corroded by acidic fluorides.
The physical properties of these inks, such as surface tension, viscosity or viscoelasticity, must be within the bounds required for jetting.

The etching process:
The etchant must be suitable to be effective in small volumes (the concentration of etch products rises rapidly in small volumes; this must not affect the etching process negatively).
The etchants must etch under conditions, which are compatible with other cell materials (i.e. not significantly etch silicon).
The ink must be physically positionable onto the surface (therefore the ink viscosity must be balanced along with surface energies and tensions).
The etching compositions must not contain elements that inadvertently dope the cell (e.g. metal cations).
Products, which are built by the etching process, must be easily removable in a later washing step.
For some applications etching must result in a uniform depth across the pattern.

Thus it is an object of the present invention to provide a suitable ink composition, which is compatible especially with common print heads.

### DETAILED DESCRIPTION OF THE INVENTION

Unexpectedly by experiments a new acidic, fluoride comprising etching composition is found, which overcomes the problems related with the acidic properties of common compositions leading to corrosion of known print heads.

The etching composition according the invention comprises an aqueous solution of at least a quaternary ammonium fluoride salt having the general formula:

R¹R²R³R⁴N+F⁻

wherein
R¹ —CHYₐ—CHY_{b}Y_{c}, which consist of groups, wherein two, three or four of the nitrogen attachments form part of a ring or a ringsystem and
Yₐ, Y_{b}, and Y, H, alkyl, aryl, heteroaryl,
R², R³ and R⁴ independently from each other equal to R¹ or alkyl, alkylammoniumfluoride, aryl, heteroaryl or —CHYₐ—CHY_{b}Y_{c},
   with the proviso that by elimination of H in —CHYₐ—CHY_{b}Y_{c} volatile molecules are generated.

In said quaternary ammonium fluoride salts more than one N⁺F⁻ functionality may be present.

In a preferred embodiment the etching composition according to the invention comprises a quaternary ammonium fluoride salt, wherein the nitrogen of N—CHYₐ—CHY_{b}Y, forms part of a pyridinium or imidazolium ring system. Good etching results may be generated with etching compositions containing at least one tetraalkylammonium fluoride salt, which is added as an active etching compound. Especially preferred are compositions, wherein the quaternary ammonium fluoride salt comprises at least one alkyl group being an ethyl or butyl group or a larger hydrocarbon group having up to 8 carbon atoms. A suitable quaternary ammonium fluoride salt may be selected from the group EtMe₃N⁺F⁻, Et₂Me₂N⁺F⁻, Et₃MeN⁺F⁻, Et₄N+F⁻, MeEtPrBuN⁺F⁻, ⁱPr₄N⁺F⁻, ⁿBu₄N⁺F⁻, ^{s}Bu₄ N⁺F⁻, Pentyl₄N⁺F⁻, OctylMe₃N⁺F⁻, PhEt₃N⁺F⁻, Ph₃EtN⁺F⁻, PhMe₂EtN⁺F⁻, Me₃N⁺CH₂CH₂N⁺Me₃F⁻₂,

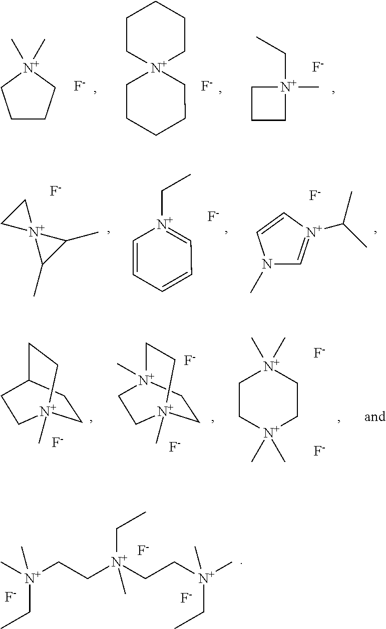

In general, etching compositions according to the present invention comprise at least one quaternary ammonium fluoride salt in a concentration in a range >20% w/w to >80% w/w. The etching compositions may comprise at least an alcohol besides of water as a polar solvent or other polar solvents and optionally surface tension controlling agents.

Suitable solvents are selected from the group ethanol, butanol, ethylene glycol, acetone, methyl ethyl ketone (MEK), and methyl n-amyl ketone (MAK), gam ma-butyrolactone (GBL), N-methyl-2-pyrrolidone (NMP), dimethyl sulfoxide (DMSO), and 2-P (so-called Safety Solvent #2-P) or from their mixtures.

Other compounds may be added to the ink composition to enhance the properties of the formulation. These compounds may be surfactants, especially volatile surfactants or co-solvents, which are suitable to adjust the surface tension of the ink and to enhance wetting of the substrate, the etching rate and film drying.

Suitable buffers for the adjustment of the pH and for reducing the head corrosion are especially volatile buffers, like amines and especially amines from which the avtive etchant may be derived (e.g. Et₃N for Et₄N⁺F⁻).

In a very preferred embodiment the etching composition according to the present invention is a printable ‘hot melt’ material, which is composed of pure salts, which are fluidized by heating for the printing step.

In general the etching compositions are printable at a temperature in the range of room temperature to 300° C., preferably in the range of room temperature to 150° C. and particularly preferred in the range of room temperature to 100° C. and especially preferred in the range of room temperature to 70° C.

This newly designed ink shows no or very low etching capability when it is stored in a tank, in the print head or when it is jetted onto the surface, which shall be structured. But the desired etchant will be developed by decomposition when the substrate is heated. This means a compound of the printed ink composition will decompose to an active etching agent, which then etches silicon oxides, nitrides, oxy-nitrides or similar surfaces, including glass. Advantageous etching results were entirely unexpected, because earlier experiments revealed insufficient etching results because of very low etching rates.

Quaternary ammonium fluoride salts (including TAAF), comprising at least one alkyl group being an ethyl group or a larger hydrocarbon, leads by elimination due to heating to a quaternary ammonium hydrogen bifluoride salt, which may include tetraalkylammonium compounds, as the active etchant, a trisubstituted amine, (including aromatic nitrogens, trialkylamine etc) and an alkene.

Thus, an active etchant can be generated for the structuring of the substrate surface at a high etching rate.

Advantageous etching results can be achieved, if compositions are applied, wherein for example all alkyl groups of the included quaternary ammonium fluoride salts are butyl. Due to heating of, for example, in this special embodiment tetrabutylammonium fluoride salt, tributylamine and 1-butene are generated and evaporated to the gas phase, leaving only tetrabutylammonium hydrogen bifluoride on the substrate as the active etchant.

This means, whereas Bu₄N⁺ F⁻ is non-etching, the etching activity of decomposition products like quaternary ammonium hydrogen bifluoride salts, especially like Bu₄N⁺ HF₂⁻ is excellent. These compounds are useful as active etchants. In the reaction as disclosed volatile byproducts like CH₃CH₂CH═CH₂ (volatile) and Bu₃N (volatile) are generated.

This reaction may be induced at the substrate surface by heating from the underside, for example on a hot plate or from the top side by irradiation by an IR heater, but also from all around in an oven.

The generation of needed HF for the etching reaction can be induced as required. After consumption of HF from the generated hydrogen bifluoride moiety in the etching reaction, the remaining quaternary ammonium fluoride may take part in the same decomposition cycle. In this manner a quantitative production of HF is obtained from the starting fluoride salt and the reaction can be supported as long as needed.

The deposition of the ink may be facilitated/aided/supported by so-called concept of bank structures. Bank structures are features on the surface which form canal-like arrays by which the inks may be easily deposited. The ink deposition is facilitated by surface energy interactions providing both, the ink and the bank materials opposite, expelling characteristics, so that the ink is forced to fill up the channels defined by bank materials without wetting the banks itself. If desirable, the bank material may possess boiling points higher than those required for the etching process itself. After completion of the etching process, the banks may be easily rinsed off by appropriate cleaning agents or alternatively the substrate is heated up until the banks have been evaporated completely. Typical bank materials may comprise the following compounds and/or mixtures thereof: nonylphenol, menthol, a-terpeniol, octanoic acid, stearic acid, benzoic acid, docosane, pentamethylbenzene, tetrahydro-1-naphthol, dodecanol and the like as well as photolithographic resists, polymers like polyhydrocarbons, e.g. —(CH₂CH₂)ₙ⁻, polystyrene etc. and other types of polymers.

Thus, the object of present invention is also a method for the etching of inorganic layers in the production of photovoltaic or semiconducting devices comprising the steps of
a) contactless application of an etching composition according to one or more of the claims 1 to 11 onto the surface to be etched,
   and
b) heating the applied etching composition to generate or activate the active etchant and etching the exposed surface areas of functional layers.

Preferably the etching composition is heated to a temperature in the range of room temperature to 100°, preferably up to 70° C., before the printing or coating step, and when the etching composition is applied to the surface, it is heated to a temperature in the range of 70 to 300° C. in order to generate or activate the active etchant, with the result, that the etching of the exposed surface areas of functional layers only begins after the heating to a temperature in the range 70 to 300° C. The heated etching composition is applied by spin or dip coating, drop casting, curtain or slot dye coating, screen or flexo printing, gravure or ink jet aerosol jet printing, offset printing, micro contact printing, electrohydrodynamic dispensing, roller or spray coating, ultrasonic spray coating, pipe jetting, laser transfer printing, pad or off-set printing. Advantageously the method according to the present invention may be applied for the etching of functional layers or layer stacks consisting of

Silicon oxide (SiOₓ), Silicon nitride (SiNₓ), Silicon oxy nitrides (SIₓO_{y}N_{z}), Aluminium oxide (AlOₓ), Titanium oxide (TiOₓ) and amorphous silicon (a-Si).

As a result, semiconducting devices or photovoltaic devices with improved performances produced by carrying out the method of the present invention are also the object of the present invention.

### Preferred Embodiments

Suitable quaternary ammonium fluoride salts, which are useful in the etching process as disclosed, are of the general formula:

R¹R²R³R⁴N⁺F⁻

wherein
R¹ —CHYₐ—CHY_{b}Y_{c}, which consist of groups, wherein two, three or four of the nitrogen attachments form part of a ring or a ringsystem and
Yₐ, Y_{b}, and Y_{c} H, alkyl, aryl, heteroaryl,
R², R³ and R⁴ independently from each other equal to R¹ or alkyl, alkylammoniumfluoride, aryl, heteroaryl or —CHYₐ—CHY_{b}Y_{c},
   with the proviso that by elimination of H in —CHYₐ—CHY_{b}Y_{c}, especially from alkyl, aryl or heteroaryl olefin, volatile molecules are generated.

In said quaternary ammonium fluoride salts more than one N⁺F⁻ functionality may be present.

—CHYₐ—CHY_{b}Y_{c} may consist of groups, wherein two, three or four of the nitrogen attachments form part of a ring or a ringsystem. Also included are N-alkyl heteroaromatic ammonium fluoride salts where the nitrogen forms part of an aromatic ring, like in pyridium and imidazolium salts.

Examples of corresponding groups are exemplified below.

Examples of suitable ammonium salts include but are not limited to:

### EtMe₃N⁺F⁻

### Et₂Me₂N⁺F⁻

### Et₃MeN⁺F⁻

### Et₄N⁺F⁻

### MeEtPrBuN⁺F⁻

ⁱPr₄N⁺F⁻
ⁿBu₄N⁺F⁻
^{s}Bu₄N⁺F⁻

### Pentyl₄N⁺F⁻

### OctylMe₃N⁺F⁻

### PhEt₃N⁺F⁻

### Ph₃EtN⁺F⁻

### PhMe₂Et N⁺F⁻

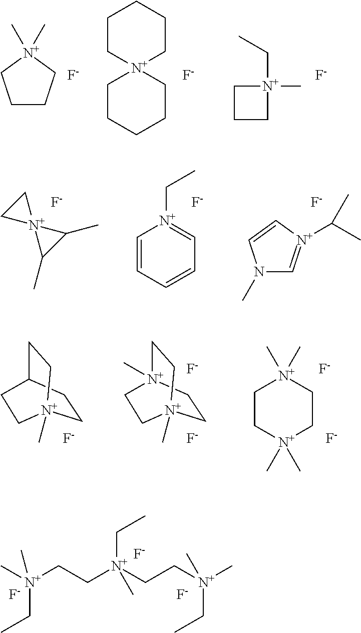

In a suitable inkjetable composition according to the invention the TAAF salt is dissolved in a solvent at a high concentration, typically at a concentration >20% w/w and especially >80% w/w. Ideally the highest concentration as possible of the ammonium fluoride is added to form a jettable solution, which is resilient to precipitation.

The composition according to the present invention may comprise a solvent. Preferably it comprises polar solvents like alcohols beside of water, but also other solvents may have advantageous properties. Thus solvents like methanol, ethanol, n-propanol, iso-propanol, n-butanol, t-butanol, iso-butanol, sec-butanol, ethylene glycol propylene glycol and mono- and polyhydric alcohols having higher carbon number and others, like ketones, e.g. acetone, methyl ethyl ketone (MEK), methyl n-amyl ketone (MAK) and the like, and mixtures thereof may be added. The most preferred solvent is water.

The compositions are easily prepared simply by combining the ammonium salt, the solvent(s) and optionally one or more compounds influencing the printing properties, and mixing these compounds together to form a homogeneous composition.

In a special embodiment of the invention the composition may consist of a material or a mixture of compounds, which is printable as a 100% ‘hot melt’ material. For example the composition may be composed of pure salts, which are fluidized by heating and the necessary viscosity is obtained by heating. Suitable mixtures can be composed of different TAAFs forming liquids at low melting points or composed of different TAAFs, forming mixtures of liquids and solids. In general TAAFs with alkyl chains having different chain lengths have lower melting points.

Suitable TAAFs have the formula (R)₄NF, and can be described as the fluoride salt of a tetraalkylammonium ion. Each alkyl group, R, of the ammonium ion has at least one and may have as many as about 22 carbon atoms, i.e., is a C₁₋₂₂alkyl group, with the proviso that at least one the four R groups is at least a group having two or more carbon atoms. The carbon atoms of each R group may be arranged in a straight chain, a branched chain, a cyclic arrangement, and any combination thereof. Each of the four R groups of TAAF are independently selected, and thus there need not be the same arrangement or number of carbon atoms at each occurrence of R in TAAF, if one of the R groups has more than one carbon atoms. For example, one of the R groups may have 22 carbon atoms, while the remaining three R groups each have one carbon atom. Tetraethylammonium fluoride (TEAF) is a preferred TAAF. A preferred class of TAAF has alkyl groups with two to about four carbon atoms, i.e., R is a C₂₋₄alkyl group. The TAAF may be a mixture, e.g., a mixture of TMAF and TEAF.

Tetramethylammonium fluoride (TMAF) is available commercially as the tetrahydrate, with a melting point of 39°-42° C. The hydrate of tetraethylammonium fluoride (TEAF) is also available from the Aldrich Chemical Co. Either of these materials, which are exemplary only, may be used in the practice of the present invention. Tetraalkylammonium fluorides which are not commercially available may be prepared in a manner analogous to the published synthetic methods used to prepare TMAF and TEAF, which are known to one of ordinary skill in the art.

For a good etching result enough material must be deposited onto the layer, which has to be treated. Entirely etching of the SiNₓ layer is mandatory for low resistance connections to the underlying silicon. This may require a number of print passes to be performed with heating. For an economical process the number of printing passes has to be low.

The surfaces, which are to be treated, may be coated or printed by a variety of different methods including the following examples, however are not limited to them: spin or dip coating, drop casting, curtain or slot dye coating etc, screen or flexo printing, gravure or ink jet aerosol jet printing, offset printing, micro contact printing, electrohydrodynamic dispensing, roller and spray coating, ultrasonic spray coating, pipe jetting, laser transfer printing, pad and off-set printing. Depending on the nature of the etching process and on the surface different methods for the application of a suitable etchant are chosen. In each case an optimized etching composition has to be taken for the special process.

Definition and resolution of features on the surface to be printed and etched, respectively, may be advantageously supported by application of bank structures keeping droplets of deposited ink on its place intended if necessary.

According to the present invention preferred IJ inks are applied showing the following physical properties:
surface tension of the ink composition >20 dyne/cm and <70 dyne/cm, more preferably >25 dyne/cm and <65 dyne/cm;
ink is preferably filtered to less than 1 μm and more preferably to less than 0.5 μm;
viscosity of the ink composition must be in the range >2 cps and <20 cps at the jetting temperature;
preferably the jetting temperature is in the range of room temperature to 300° C., more preferably in the range of room temperature to 150° C. and most preferably in the range of room temperature to 70° C.;
preferably the etching temperature is in the range of 70° C. to 300° C., more preferably in the range of 100° C. and 250° C. and most preferably in the range of 150° C. to 210° C.;
at jetting temperature the ink may be a ‘hot melt’ type i.e. liquid but solid at room temperature [Hot melt inks are used to fix the etchant on the surface and more accurately define the etch area.];

These IJ inks may comprise:
additives like surfactants, low surface tension co-solvents including fluorinated solvents or others, which are suitable reduce the surface tension of the ink;
binders to fix the etchant on drying and define the etch area more accurately;
thermally and/or photochemically cross linkable binders to fix the ink on the substrate.
different carrier solvents or mixtures of solvents to formulate the ink, and thus affecting the kinetics of drying and viscosity change, whereby the form of the printed structures such as highly coffee stained features may be programmed to hold secondary depositions of ink.

Other processes for applying the inks need ideal fluid properties to achieve good etching results.

Etching processes according to the present invention are also applicable if typical layers or layer stacks in photovoltaic devices have to be treated for purpose of local and selective opening of surface passivation and/or antireflective layers and layer stacks. Typically, such layers and stacks are composed of the following materials:
Silicon oxide (SiOₓ)
Silicon nitride (SiNₓ)
Silicon oxy nitrides (SiₓO_{y}N_{z})
Aluminium oxide (AlOₓ)
Titanium oxide (TiOₓ)
Stacks of silicon oxide (SiOₓ) and silicon nitride (SiNₓ), so-called NO-stacks
Stacks of silicon oxide (SiOₓ), silicon nitride (SiNₓ) and silicon oxide (ONO-stacks)
Stacks of aluminium oxide (AlOₓ) and silicon oxide (SiOₓ)
Stacks of aluminium oxide (AlOₓ) and silicon nitride (SiNₓ)
Stacks of amorphous silicon (a-Si) and silicon oxide (SiOₓ)
Stacks of amorphous silicon (a-Si) and silicon nitride (SiNₓ)

All singly mentioned materials, including amorphous silicon (a-Si), may additionally be partially hydrogenated, namely hydrogen-containing. The individual hydrogen contents of the materials mentioned depend on individual parameters of deposition. In particular amorphous silicon (a-Si) may partially comprise ammonia (NH₃) intercalated or otherwise incorporated.

### Target Device Processes

The materials as well as layer stacks mentioned under preceding paragraph, however, not limited to those explicitly mentioned there, may be applied during the manufacture of either standard or conventional solar cells as well as for advanced, so-called high-efficiency, devices. Under the term ‘standard solar cell’, devices are meant which comprise the features shown in FIG. 1, however, variations from items outlined there are also known. FIG. 1 shows a simplified flow chart demonstrating the necessity of structuring of dielectric layers for the manufacturing of advanced solar cell devices.

Structuring steps are needed for:
Textured front and rear side; under certain circumstances, flat and polished rear sides; thus surfaces deliberated from specific texture topographies, which may be beneficial.
The emitter is located on/in the front side being mostly wrapped around the edges of the solar cells, prevalently covering the complete rear side too.
The emitter is mostly capped by a SiNₓ-layer originating from PECVD-deposition (PECVD=plasma enhanced chemical vapour deposition), this layer serves as surface passivation besides being responsible for reflectance reduction of the device (ARC).
On top of the ARC, virtually, metal contacts are formed somehow, mostly by thick film deposition, in order to enable charge carriers to leave device for traversing exterior circuitry after metal contacts being driven through the ARC-layer.
The rear side is mostly characterized by residual n-doped layer as well as by a less precisely defined layer stack of Al-alloyed silicon, Si-alloyed aluminium as well as sintered aluminium flakes, whereby the latter stack of layers serves as so-called back-surface field (full BSF) as well as rear electrode.
Solar cell device is completed by something denoted as edge isolation which serves for disconnecting front side exposed emitter from rear side carrying electrode by wipe out of ohmic shunt; this shunt elimination may be achieved by different process technologies, having a direct impact on above-mentioned general description of solar cells architecture. Thus afore-sketched device description is prone to process variations.

The manufacture of state-of-the art or just above-depicted ‘standard’ solar cells omits the need of two-dimensional processes of (surface) structuring, except for printing of metal paste. Advances for obtaining significant benefits in conversion efficiencies of solar devices, however, express urgent needs for structuring processes in general. Approaches for solar cells, whose architectures are inherent for structuring steps, however are not limited to those subsequently mentioned, are:
1. Selective emitter solar cells, comprising a
   a) one-step selective emitter or
   b) two-step selective emitter
2. Solar cells being metallised by a “direct metal approach” or “direct metallization”
3. Solar cells comprising a local back-surface field
4. PERL-solar cells (passivated emitter rear locally diffused)
5. PERC-solar cells (passivated emitter rear contact)
6. PERT (passivated emitter rear totally diffused)
7. Interdigitated back contact cells
8. Bifacial Solar Cells

In the following context, only brief descriptions of technological features regarding afore-mentioned solar cell architectures are given in order to clarify the need for structuring processes. Further readings may be easily found for persons skilled in the art.

The concept of selective emitter solar cell makes usage from beneficial effects originating from the adjustment of different emitter doping levels. In principal conventionally manufactured solar cells require a need for comparably high emitter doping levels at this surface areas, where latter metallization contact will be formed in order to achieve good ohmic rather than Schottky-related semiconductor-metal-contacts, and thus contact resistances. This may be achieved by low emitter sheet resistances (thus, emitters bearing a high content of dopants). On the other hand, relatively low doping levels (high sheet resistances) are requested for enhancing the spectral response of the solar cells as well as for improving minority carrier lifetimes within the emitter, both beneficially influencing conversion performance of the device. Both needs basically rule out each other always requesting compromises between optimizing contact resistance at spectral responses cost and vice versa. With the implementation of a structuring process within process chain of device manufacturing, definition of regions of formation of regions bearing high and low sheet resistances will be easily accomplished by the aid of commonly known technology of masking (e.g. by SiOₓ, SiNₓ, TiOₓ, etc.). Masking technology, however, presupposes possibilities of either structured mask deposition or the structuring of deposited masks, which refers to the present invention.

The concept of ‘direct metallization’ refers to the opportunity of a metallization process which will be carried out directly on for instance emitter-doped silicon. Nowadays, conventional creation of metal contacts is achieved by thick film technology, namely mainly by screen-printing, where a metal-containing paste is printed onto the ARC-capped silicon wafer surface. The contact is formed by thermal treatment, namely a sintering process, within which the metal paste is forced to penetrate the front surface capping layer. Actually, front as well as rear surface metallization, or more precisely contact formations, are normally performed within one process step being called ‘co-firing’. In particular the ability of contact formation at the front is mainly attributable to special paste constituents (glass frits) which on the hand are essential, however, on the other hand lower the metal filling density of the paste, thus, besides other impacting factors, giving rise to lower conductivities than for instance contacts being deposited by electro-plating. Since front surfaces of solar cells conventionally lack of selectively opened windows for advanced front side metallization, paste sintering processes may not be omitted. Which in turn refers to the present invention: local opening of front side covered by dielectric layers may be easily and versatile achieved, thus making ‘direct metallization’ approaches technological facile accessible. Those approaches may comprise techniques like currentless deposition of metal seed layers into openings of structured dielectric layers forming metal silicides as primary contacts after annealing and being subsequently reinforced by electro-plating or such like printing metal pastes without glass frits.

The concept of local back surface field makes uses of benefit of enabling spot-like and stripe-like openings or those having other geometrical features in rear surface dielectrics getting afterwards highly doped by the same ‘polarity’ as the base itself. These features, the latter base contacts, are created in a passivating semiconductor surface layer or stack like such comprising for instance SiO₂. The passivating layer is responsible for an appropriate surface capping while otherwise the surface would be able to act as charge carrier annihilator. Within this passivating layer, contact windows have to be generated in order to achieve traversing of charge carriers to exterior circuitry. Since such windows need to be connected to a (metal) conductor, however, on the other hand, metal contacts are known to be strongly recombination active (annihilation of charge carriers), as less as possible of the silicon surface should be metallised directly without on the other hand affecting the overall conductivity. It is known that contact areas in the range of 5% of the whole surface or even less are sufficient for appropriate contact formation to semi conducting material. In order to achieve good ohmic contacts rather than Schottky-related ones, doping level (sheet resistance) of base dopants below the contacts should be as high as possible. Additionally, increased doping levels of base dopants behave like a mirror (back surface field) for minority charge carriers, reflecting them from base contacts and thus significantly reducing recombination activity at either semiconductor surface or especially base metal contacts. In order to achieve a local back surface field, the passivating layer on top of the rear surface has to be opened locally, what in turn refers to the subject of present invention.

The concepts of PERC-, PERL- and PERT-solar cells do all comprise individual above-depicted concepts of selective emitter, local back surface field as well as ‘direct metallization’. All these concepts are merged together to architectures of solar cells being dedicated to achieve highest conversion efficiencies. The degree of merging of those sub-concepts may vary from type of cell to cell as well as from ratio of being able to be manufactured by industrial mass production. The same holds true for the concept of interdigitated back contact solar cells.

Bifacial solar cells are solar cells, which are able to collect light incidenting on both sides of the semiconductor. Such solar cells may be produced applying ‘standard’ solar cell concepts. Advances in performance gain will also make the usage of the concepts depicted above necessary.

For better understanding and in order to illustrate the invention, examples are given below which are within the scope of protection of the present invention. These examples also serve to illustrate possible variants. Owing to the general validity of the inventive principle described, however, the examples are not suitable for reducing the scope of protection of the present application to these alone.

The temperatures given in the examples are always in ° C. It furthermore goes without saying that the added amounts of the components in the composition always add up to a total of 100% both in the description and in the examples.

The present description enables the person skilled in the art to use the invention comprehensively. If anything is unclear, it goes without saying that the cited publications and patent literature should be used. Correspondingly, these documents are regarded as part of the disclosure content of the present description and the disclosure of cited literature, patent applications and patents is hereby incorporated by reference in its entirety for all purposes.

### EXAMPLES

### Example 1

### Printing Lines on Polished Wafers with Tetraethylammonium Fluoride

An ink is formulated with 62.5% tetraethylammonium fluoride in deionised water. This ink is then printed with a Dimatix DMP using a 10 pl IJ head onto a polished Si wafer with a SiNₓ layer of approximately 80 nm. The substrate is heated to 175° C. before a line was printed with 40 μm drop spacing. Six further applications of the ink are printed at one minute intervals. After the final deposition the substrate is kept at 175° C. for a further minute before removal of the residue using a water rinse.

In FIG. 2 given images demonstrate the increasing depth of etch upon subsequent deposition of the etching ink. The images show from left to right 1, 2, 3, 4, and 5 print passes on a polished wafer after washing with water. Printing was performed with a substrate temperature of 175° C., a drop spacing of 40 μm, and with a one minute gap between the print passes.

FIG. 3 shows the surface profile of an etched SiNₓ wafer, which is obtained after seven depositions of etchant and shows the achieved extent of etching.

### Example 2

### Printing Lines on Textured Wafers Tetraethylammonium Fluoride

An ink is formulated with 62.5% tetraethylammonium fluoride in water. This ink is then printed with a Dimatix DMP onto a textured Si wafer with a SiNₓ layer of approximately 80 nm. The substrate is heated to 175° C. before a line is printed with 40 μm drop spacing. Four further applications of the ink are printed at one minute intervals. After the final deposition the substrate is kept at 175° C. for a further minute before removal of the residue using a water rinse.

In FIG. 4 the increasing depth of etch upon subsequent deposition of the etching ink is demonstrated. From left to right the images show the effect of 1, 2, 3, 4, and 5 print passes by use of a composition according to example 2 on a polished wafer after washing with water.

Printing was performed with a substrate temperature of 175° C., a drop spacing of 40 μm, and with a one minute gap between the different print passes.

### Example 3

### Printing Holes on Polished Wafers with Tetraethylammonium Fluoride

An ink is formulated with 62.5% tetraethylammonium fluoride in water. This ink is then printed with a Dimatix DMP onto a polished Si wafer with a SiNₓ layer of approximately 80 nm. The substrate is heated to 175° C. before a row of drops is deposited onto the substrate. Siₓ further applications of the ink are printed at one minute intervals. After the final deposition the substrate is kept at 175° C. for a further minute before removal of the residue using a water rinse.

In FIG. 5 the images demonstrate the etching obtained after seven print passes by using a composition according to example 3. A row of holes is shown, which is etched into a SiNₓ layer on a polished wafer after seven print passes and after cleaning with water. Printing was performed with a substrate temperature of 175° C. and with a one minute gap between the print passes.

### Example 4

### Printing Lines on Polished Wafers with Tetrabutylammonium Fluoride

An ink is formulated with 62.5% tetrabutylammonium fluoride in water. This ink is then printed with a Dimatix DMP onto a textured Si wafer with a SiNₓ layer of approximately 80 nm. The substrate is heated to 175° C. before a line is printed with 40 μm drop spacing. Four further applications of ink are printed at one minute intervals. After the final deposition the substrate is kept at 175° C. for a further minute before removal of the residue using a water rinse.

In FIG. 6 the image demonstrates the etched track into SiNₓ on a polished wafer. The etching achieved with tetrabutylammonium fluoride after five print passes. The wafer was cleaned with water. Printing was performed with a substrate temperature of 175° C., a drop spacing of 40 μm, and with a one minute gap between the print passes.

### Comparative Example 5

Attempted etching using tetramethylammonium fluoride on polished wafers (showing the need to eliminate an alkene in the chemical conversion to HF₂⁻-salt)

An ink is formulated with 62.5% tetramethylammonium fluoride in water. This ink is then applied onto a textured Si wafer with a SiNₓ layer of approximately 80 nm. The substrate is heated to 175° C. for 5 min before removal of the residue using a water rinse.

FIG. 7 demonstrates that no effective etching is achieved with tetramethylammonium fluoride in a composition as disclosed in example 5. The image shows the textured wafer with “stained” SiNₓ layer after attempted etching for 5 minutes at a substrate temperature of 175° C. the ink was placed onto the wafer by doctor blading. The wafer was cleaned by rinsing with water.

### Example 6

### Printing Lines on Polished Wafers with N,N′-dimethyl-1,4-diazoniumbicyclo[2.2.2]octane difluoride

An ink is formulated with 50% N,N′-dimethyl-1,4-diazoniumbicyclo[2.2.2]octane difluoride in deionised water. This ink is then printed with a Dimatix DMP using a 10 pl IJ head onto a polished Si wafer with a SiNx layer of approximately 80 nm. The substrate is heated to 180° C. before a line is printed with 40 μm drop spacing. Four further applications of ink are printed at one minute intervals. After the final deposition the substrate is kept at 180° C. for a further minute before removal of the residue using a water rinse.

In FIG. 8 the images demonstrate the increasing depth of etch upon subsequent deposition of the etching ink as disclosed in example 6. From left to right the images show 1, 2, 3, 4, and 5 print passes on a polished wafer after washing with water. Printing was performed with a platen temperature of 180° C., a drop spacing of 40 μm, and with a one minute gap between the print passes.

FIG. 9 shows the surface profile of an etched SiNₓ wafer, which is obtained after three depositions of etchant and of removal of residues.

### Example 7

### Printing Lines on Polished Wafers with N,N,N′,N′-tetramethyldiethylenediammonium difluoride

An ink is formulated with 30% N,N,N′,N′-tetramethyldiethylenediammonium difluoride in deionised water. Then this ink is printed with a Dimatix DMP using a 10 pl IJ head onto a polished Si wafer with a SiNₓ layer of approximately 80 nm. The substrate is heated to 180° C. before a line is printed with 40 μm drop spacing. Three further applications of the ink are printed at one minute intervals. After the final deposition the substrate is kept at 180° C. for a further minute before removing the residues using a water rinse.

In FIG. 10 the images show from left to right the increasing depth of etch upon subsequent deposition of the etching ink after 1, 2, 3, and 4 print passes on a polished wafer after washing with water. The printing was performed with a substrate temperature of 180° C., a drop spacing of 40 μm, and with a one minute gap between the print passes.

FIG. 11 shows the surface profile of an etched SiNₓ wafer and the extend of etching, which is achieved after four depositions of an etching composition of example 7 and removing of residues.

### Example 8

### Printing Lines on Polished Wafers with N-ethylpyridinium Fluoride

An ink is formulated with 75% N-ethylpyridinium fluoride in deionised water. This ink is then printed with a Dimatix DMP using a 10 pl IJ head onto a polished Si wafer with a SiNx layer of approximately 80 nm. The substrate is heated to 180° C. before a line is printed with 40 μm drop spacing. Four further applications of ink were printed at one minute intervals. After the final deposition the substrate is kept at 180° C. for a further minute before removing the residue using an RCA-1 clean.

In FIG. 12 the images demonstrate the increasing depth of etch upon subsequent deposition of the etching ink of example 8, and from left to right after 1, 2, 3, 4, and 5 print passes on a polished wafer after removal of ink residue by RCA-1 cleaning. Printing was performed with a substrate temperature of 180° C., a drop spacing of 40 μm, and with a one minute gap between the print passes.

### Example 9

### Printing Lines on Polished Wafers with 6-azoniaspiro[5,5]undecane fluoride

An ink is formulated with 56% 6-azonia-spiro[5,5]undecane fluoride in water. This ink is then printed with a Dimatix DMP using a 10 pl IJ head onto a polished Si wafer with a SiNₓ layer of approximately 80 nm. The substrate is heated to 180° C. before a line is printed with 40 μm drop spacing. Four further applications of the ink are printed at one minute intervals. After the final deposition the substrate is kept at 180° C. for a further minute before removing residues using a water rinse.

The images in FIG. 13 demonstrate the increasing depth of etch upon subsequent deposition of the etching ink of Example 9 after 1, 2, 3, and 4 print passes from left to right on a polished wafer after washing with water. Printing was performed with a substrate temperature of 180° C. and a drop spacing of 40 μm, and with a one minute gap between print passes.

### Example 10

### Printing Lines on Polished Wafers with hexamethylethylenediammonium difluoride

An ink is formulated with 55% hexamethylethylenediammonium difluoride in deionised water. This ink is then printed with a Dimatix DMP using a 10 pl IJ head onto a polished Si wafer with a SiNx layer of approximately 80 nm. The substrate is heated to 180° C. before a line is printed with 40 μm drop spacing. Four further applications of ink are printed at one minute intervals. After the final deposition the substrate is kept at 180° C. for a further minute before removing residues using a water rinse.

The images in FIG. 14 demonstrate the increasing depth of etch upon subsequent deposition of the etching ink as described in example 10 after 1, 2, 3, 4 and 5 print passes on a polished wafer after washing with water. Printing was performed with a substrate temperature of 180° C., a drop spacing of 40 μm, and with a one minute gap between print passes.

### Example 11

### Printing Lines on Polished Wafers with Pentamethyl Triethyl Diethylenetriammonium Trifluoride

An ink is formulated with 50% pentamethyl triethyl diethylenetriammonium trifluoride in deionised water. Then this ink is printed with a Dimatix DMP using a 10 pl IJ head onto a polished Si wafer with a SiNₓ layer of approximately 80 nm. The substrate is heated to 180° C. before a line is printed with 20 μm drop spacing. Two further applications of ink are printed at one minute intervals. After the final deposition the substrate is kept at 180° C. for a further minute before removal of residues using a water rinse.

The images in FIG. 15 demonstrate the increasing depth of etch upon subsequent deposition of the etching ink of example 11 from left to right after 1, 2 and 3 print passes on a polished wafer after washing with water. Printing was performed with a substrate temperature of 180° C., a drop spacing of 20 μm, and with a one minute gap between print passes.

### Example 12

### Printing Lines on Polished Wafers with Diethyldimethylammonium Fluoride

An ink is formulated with 60% diethyldimethylammonium fluoride in deionised water. This ink is then printed with a Dimatix DMP using a 10 pl IJ head onto a polished Si wafer with a SiNₓ layer of approximately 80 nm. The substrate is heated to 180° C. before a line is printed with 40 μm drop spacing. Four further applications of the ink are printed at one minute intervals. After the final deposition the substrate is kept at 180° C. for a further one minute before removal of the residue using a water rinse.

The images in FIG. 16 demonstrate the increasing depth of etch upon subsequent deposition of the etching ink prepared as described in example 12 after 1, 2, 3, 4 and 5 print passes from left to right on a polished wafer after washing with water. Printing was performed with a substrate temperature of 180° C., a drop spacing of 40 μm, and with a one minute gap between print passes.

### Example 13

### Printing Lines on Polished Wafers with Isopropyltrimethylammonium Fluoride

An ink is formulated with 50% iso-propyltrimethylammonium fluoride in water. Then this ink is printed with a Dimatix DMP using a 10 pl IJ head onto a polished Si wafer with a SiNₓ layer of approximately 80 nm. The substrate is heated to 180° C. before a line is printed with 40 μm drop spacing. Four further applications of ink are printed at one minute intervals. After the final deposition the substrate is kept at 180° C. for a further minute before removal of residues using a water rinse.

Images of FIG. 17 demonstrate the increasing depth of etch upon subsequent deposition of the etching ink of example 13 from left to right after 1, 2, 3, 4 and 5 print passes on a polished wafer after washing with water. Printing was performed with a substrate temperature of 180° C., a drop spacing of 40 μm, and with a one minute gap between print passes.

### LIST OF INCLUDED FIGURES AND IMAGES

FIG. 1 shows a simplified flow chart demonstrating the necessity of structuring of dielectric layers for the manufacturing of advanced solar cell devices.

FIG. 2 increasing depth of etch upon subsequent deposition of the etching ink of example 1.

FIG. 3 shows the surface profile of an etched SiNₓ wafer, which is obtained after seven depositions of the etching composition of example 1 and shows the achieved extent of etching.

FIG. 4 increasing depth of etch upon subsequent deposition of the etching ink. From left to right the images show the effect of 1, 2, 3, 4, and 5 print passes by use of a composition according to example 2

FIG. 5 demonstrates the etching obtained after seven print passes by using a composition according to example 3.

FIG. 6 demonstrates the etched track into SiNₓ on a polished wafer. The etching achieved with tetrabutylammonium fluoride after five print passes

FIG. 7 demonstrates that no effective etching is achieved with tetramethylammonium fluoride in a composition as disclosed in example 5.

FIG. 8 the images demonstrate the increasing depth of etch upon subsequent deposition of the etching ink as disclosed in example 6.

FIG. 9 shows the surface profile of an etched SiNₓ wafer, which is obtained after three depositions of the etching ink of example 6 and of removal of residues.

FIG. 10 increasing depth of etch upon subsequent deposition of the etching ink of example 7

FIG. 11 shows the surface profile of an etched SiNₓ wafer and the extend of etching

FIG. 12 increasing depth of etch upon subsequent deposition of the etching ink of example 8

FIG. 13 increasing depth of etch upon subsequent deposition of the etching ink of Example 9

FIG. 14 increasing depth of etch upon subsequent deposition of the etching ink as described in example 10

FIG. 15 increasing depth of etch upon subsequent deposition of the etching ink of example 11

FIG. 16 increasing depth of etch upon subsequent deposition of the etching ink according to example 12

FIG. 17 increasing depth of etch upon subsequent deposition of the etching ink of example 13

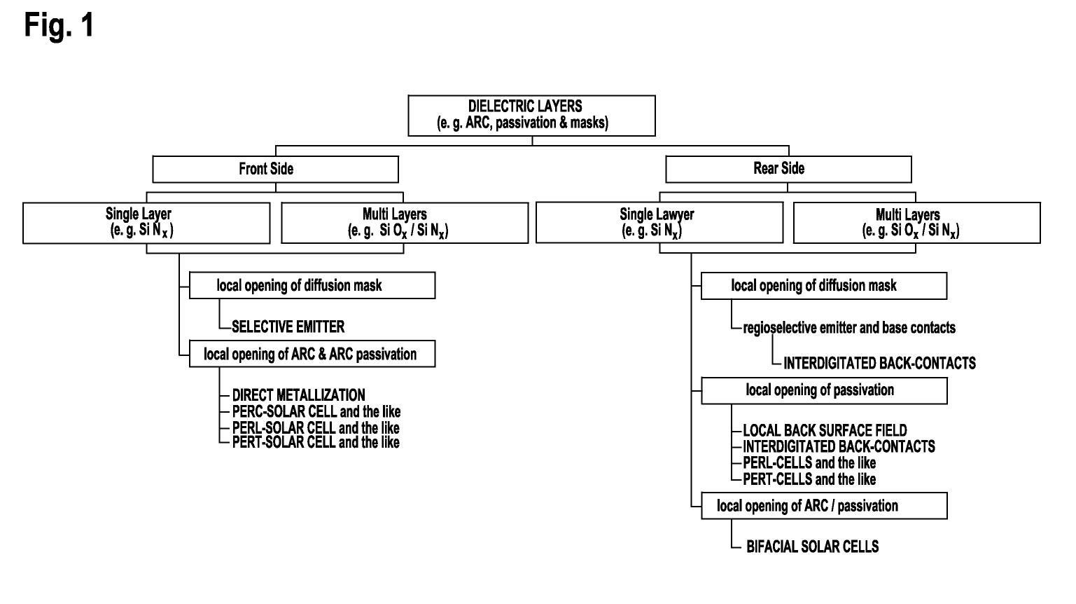

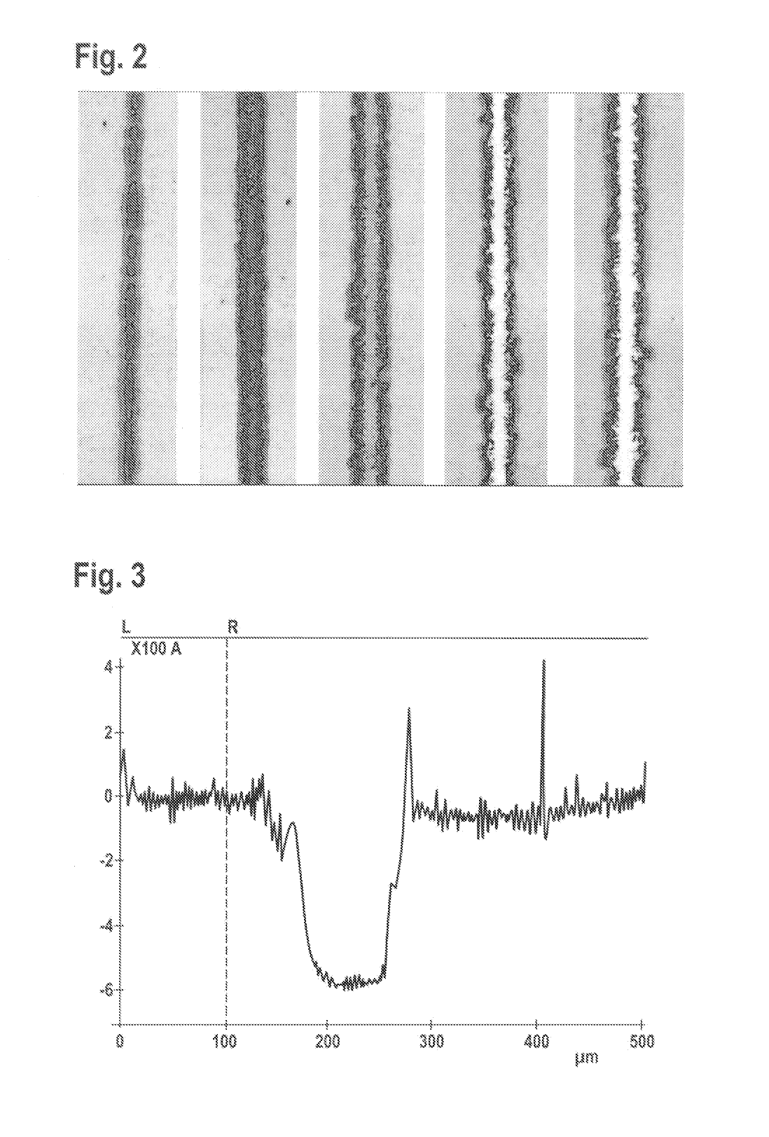

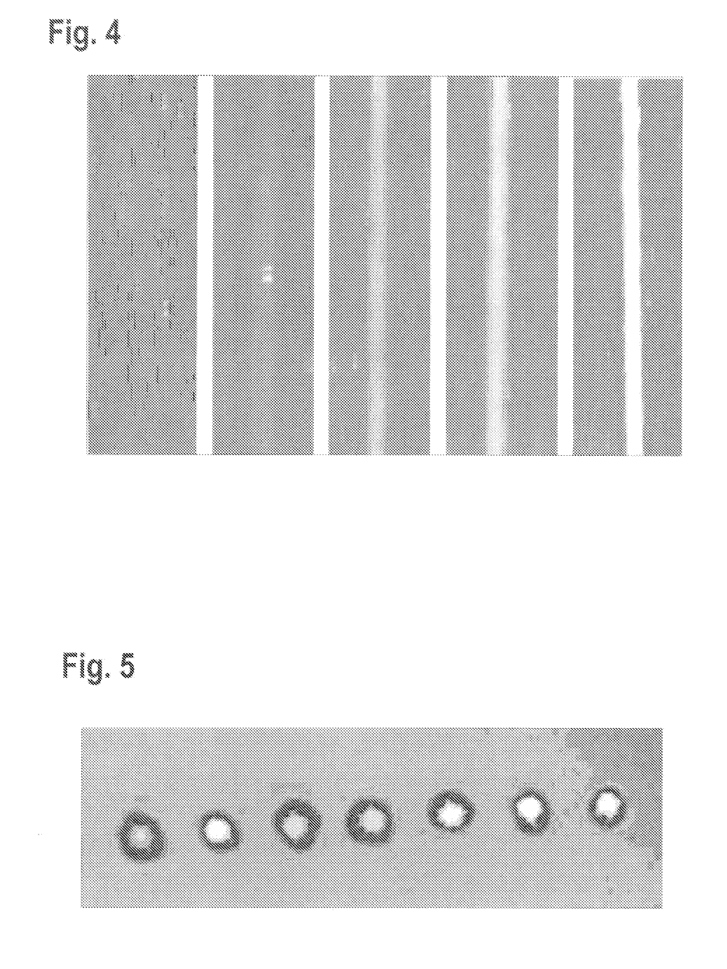

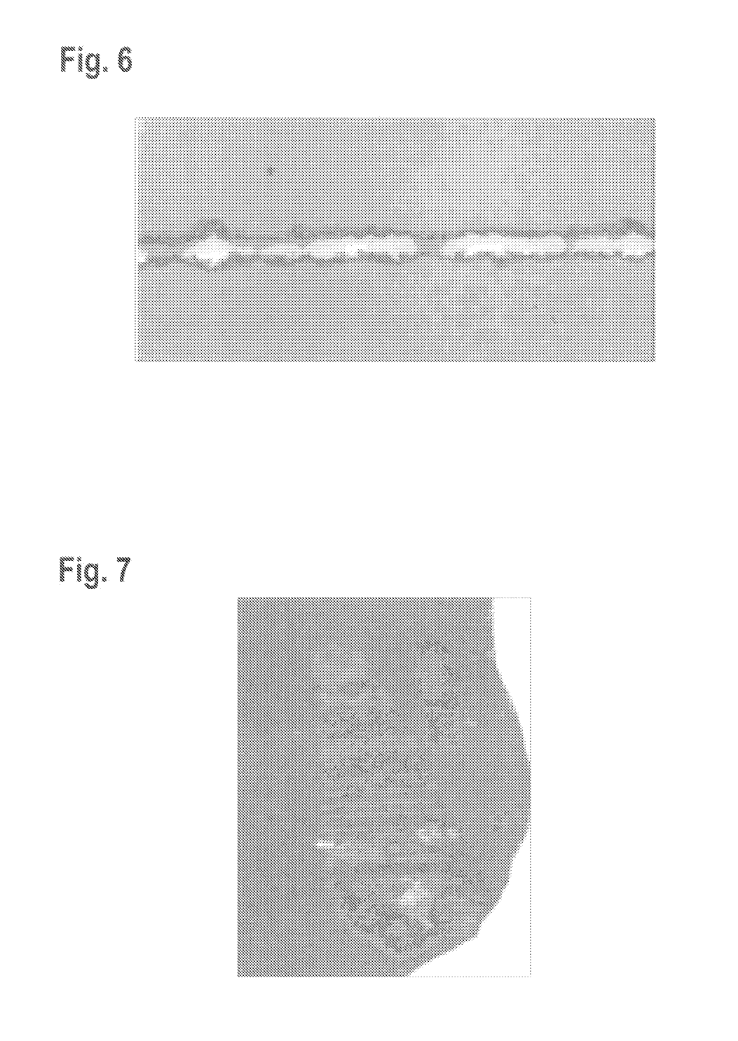

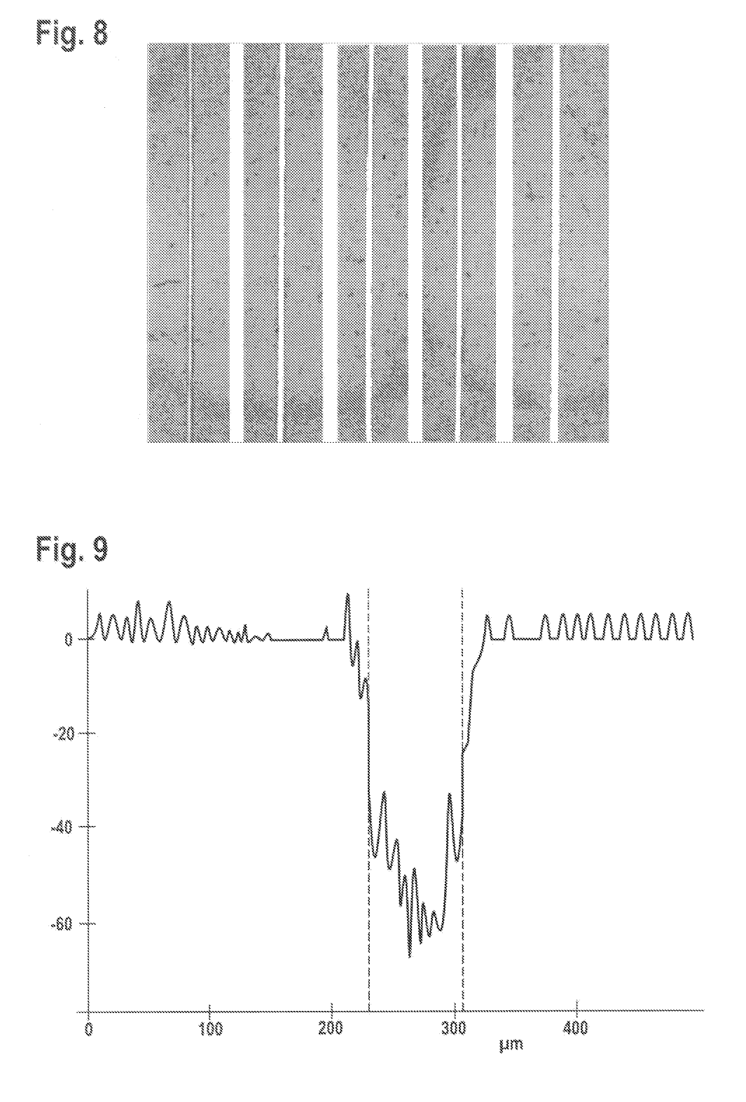

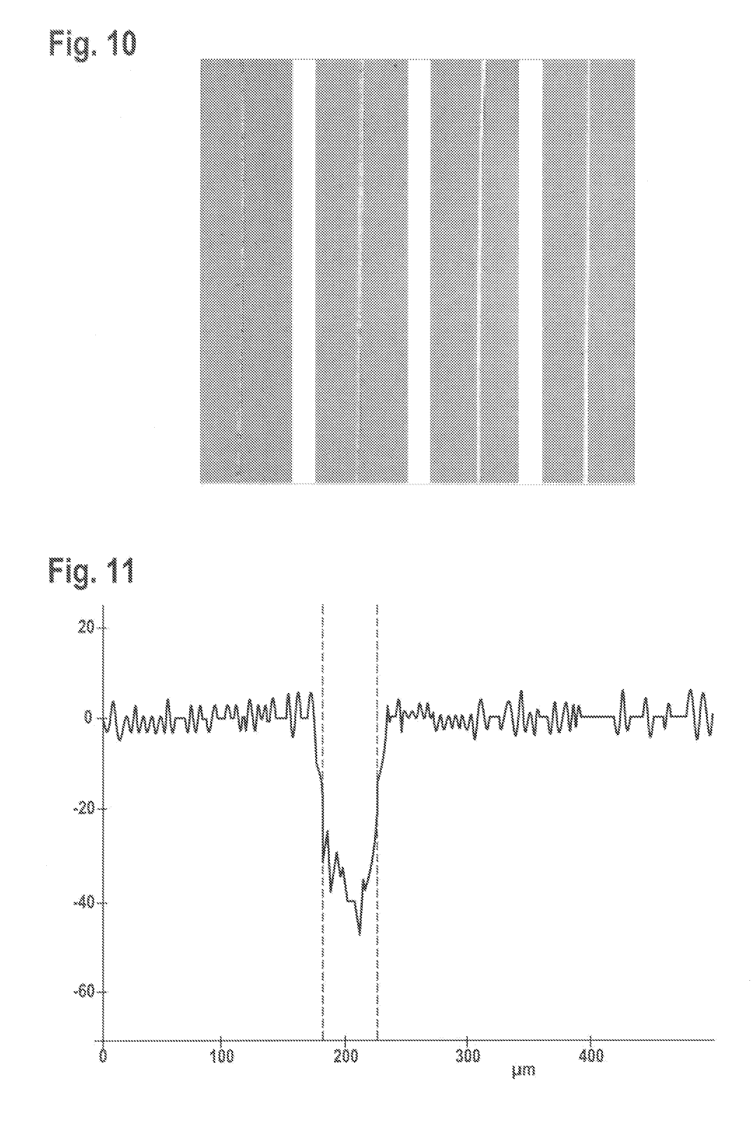

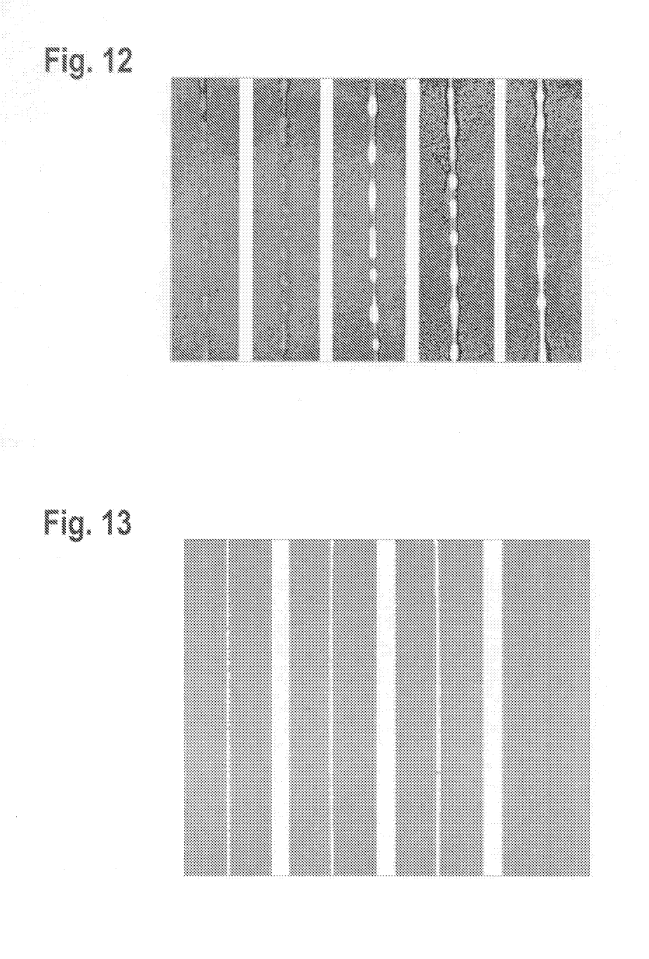

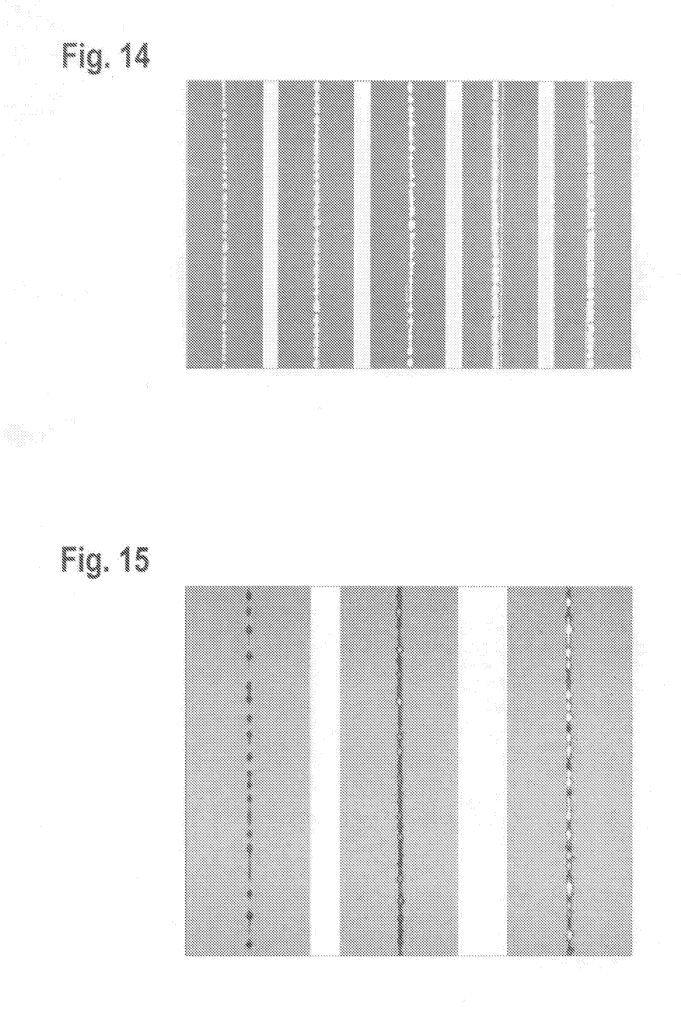

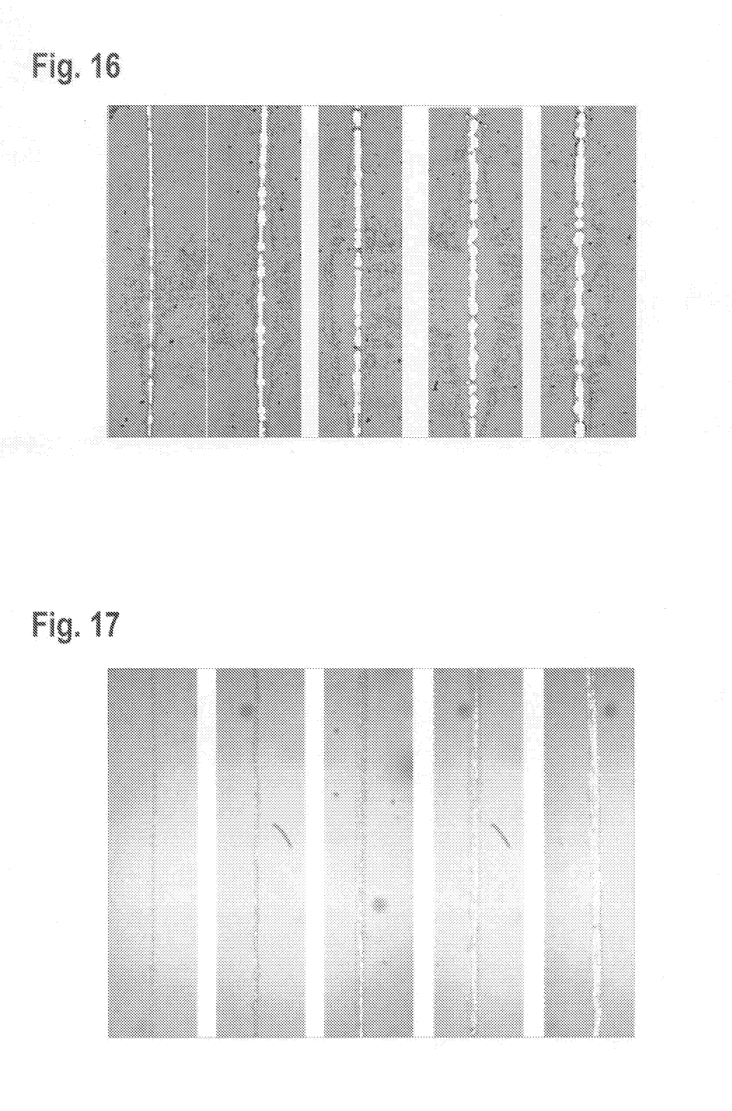

1. Etching composition comprising an aqueous solution of at least a quaternary ammonium fluoride salt having the general formula:
R¹R²R³R⁴N⁺F⁻
wherein
R¹ —CHYₐ—CHY_{b}Y_{c}, which consists of groups, wherein two, three or four of the nitrogen attachments form part of a ring or a ringsystem and
Yₐ, Y_{b}, and Y_{c} H, alkyl, aryl, heteroaryl,
R², R³ and R⁴ independently from each other equal to R¹ or alkyl, alkylammoniumfluoride, aryl, heteroaryl or —CHYₐ—CHY_{b}Y_{c},
with the proviso that by elimination of H in —CHYₐ-CHY_{b}Y_{c} volatile molecules are generated.

2. Etching composition according to claim 1 comprising a quaternary ammonium fluoride salt, wherein the nitrogen of —CHYₐ—CHY_{b}Y_{c} forms part of a pyridium or imidazolium ring system.

3. Etching composition according to claim 1 comprising at least one tetraalkylammonium fluoride salt.

4. Etching composition according to claim 3, wherein the quaternary ammonium fluoride salt comprises at least one alkyl group being an ethyl or butyl group or a larger hydrocarbon group having up to 8 carbon atoms.

5. Etching composition according to claim 1, comprising at least one quaternary ammonium fluoride salt selected from the group EtMe₃N⁺F⁻, Et₂Me₂N⁺F⁻, Et₃MeN⁺F⁻, Et₄N⁺F⁻, MeEtPrBuN⁺F⁻, ⁱPr₄N⁺F⁻, ⁿBu₄N⁺F⁻, ^{s}Bu₄N⁺F⁻, Pentyl₄N⁺F⁻, OctylMe₃N⁺F⁻, PhEt₃N⁺F⁻, Ph₃EtN⁺F⁻, PhMe₂EtN⁺F⁻,

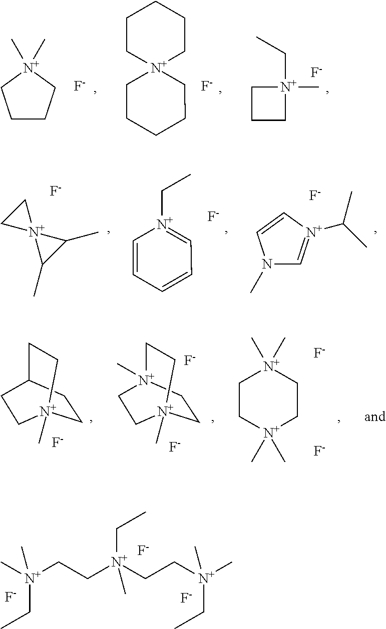

6. Etching composition according to claim 1, comprising at least one quaternary ammonium fluoride salt in a concentration in a rage >20% w/w to >80% w/w.

7. Etching composition according to claim 1, comprising at least an alcohol besides of water as solvent and optionally surface tension controlling agents.

8. Etching composition according to claim 1, comprising a solvent selected from the group of water, methanol, ethanol, n-propanol, iso-propanol, n-butanol, t-butanol, iso-butanol, sec-butanol, ethylene glycol, propylene glycol, mono- and polyhydric alcohols having higher carbon number, acetone, methyl ethyl ketone (MEK), methyl n-amyl ketone (MAK) or mixtures thereof.

9. Etching composition according to one claim 1, which is a printable ‘hot melt’ material composed of pure salts, and which are fluidized by heating.

10. Etching composition according to claim 1, comprising an etchant, which is activated at temperatures in the range of 50 to 300° C., preferably in the range of 70 to 300° C., and which is printable at a temperature in the range of room temperature to 150° C.

11. Etching composition according to claim 1, showing no or very low etching capability during storage and printing.

12. Method for the etching of inorganic layers in the production of photovoltaic or semiconducting devices comprising the steps of
a) contactless application of an etching composition according to claim 1 onto the surface to be etched,
and
b) heating the applied etching composition to generate or activate the active etchant and etching the exposed surface areas of functional layers.

13. Method of claim 12 comprising the steps of
a) contactless application of an etching composition by printing or coating, whereby the etching composition is heated to a temperature in the range of room temperature to 100° C., preferably to a temperature in the range of room temperature up to 70° C.,
and
b) heating the applied etching composition to a temperature in the range of 70 to 300° C. to generate or activate the active etchant and etching the exposed surface areas of functional layers.

14. Method according to claim 12,
characterized in that the etching composition is heated to a temperature in the range of room temperature to 70° C. and applied by
spin or dip coating, drop casting, curtain or slot dye coating, screen or flexo printing, gravure or ink jet aerosol jet printing, offset printing, micro contact printing, electrohydrodynamic dispensing, roller or spray coating, ultrasonic spray coating, pipe jetting, laser transfer printing, pad or off-set printing.

15. Method according to claim 12, wherein the heated etching composition is applied to etch functional layers or layer stacks consisting of Silicon oxide (SiOₓ), Silicon nitride (SiNₓ), Silicon oxy nitrides (SiₓO_{y}N_{z}), Aluminium oxide (AlOₓ), Titanium oxide (TiOₓ) and amorphous silicon (a-Si).

16. Semiconducting device or photovoltaic device produced by carrying out a method according to claim 12.
